(19) United States
(12) Patent Application Publication
(10) Pub. No.: US 2010/0163909 A1
(43) Pub. Date: Jul. 1, 2010

(54) MANUFACTURING METHOD AND STRUCTURE OF LIGHT-EMITTING DIODE WITH MULTILAYERED OPTICAL LENS

(76) Inventors: Ming-Hung Chen, Taiwan (CN); Shih-Yi Wen, Taiwan (CN); Hsin-Tai Lin, Taiwan (CN)

Correspondence Address: Juan Carlos A. Marquez;c/o Stites & Harbison PLLC, 1199 North Fairfax Street, Suite 900, Alexandria, VA, 22314-1437, US

(21) Appl. No.: 12/664,061

(22) PCT Filed: Sep. 27, 2007
(86) PCT No.: PCT/CN07/02829

§ 371 Date: Dec. 11, 2009

(51) Int. Cl. H01L 33/00

(52) U.S. Cl. 257/98; 438/27; 438/29; 257/99; 257/100; 257/E33.059; 257/E33.061; 257/E33.067

(57) ABSTRACT

A manufacturing method and a structure of a light-emitting diode (LED) with a multilayered optical lens are provided. The manufacturing method includes the steps of: providing an LED chip; forming at least one inner protective layer covering the LED chip and its wire connecting points; and forming an outer protective layer covering the inner protective layer. Both the inner and outer protective layers are optical resin layers while the inner protective layer is harder than the outer protective layer. The structure of the LED includes: an LED chip; at least one inner protective layer covering the LED chip and its wire connecting points; and an outer protective layer covering the said inner protective layer. The relatively hard said inner protective layer can resist external force transmitted by the outer protective layer and protect the LED chip and its wire connecting points from damage by the external force.

### BACKGROUND OF THE INVENTION

1. Technical Field

The present invention relates to a manufacturing method and a structure of a light-emitting diode (LED). More particularly, the present invention relates to a manufacturing method and a structure of an LED with a multilayered optical lens, wherein the manufacturing method and the structure are applicable to LED encapsulation.

2. Description of Related Art

As the technology of manufacturing LEDs gradually matures, the range of LED applications has been extended from low-end indicator lights and consumer electronics to general lighting and car lights. Meanwhile, LED encapsulation techniques have improved accordingly.

In terms of LED encapsulation, a conventional LED is typically encapsulated in epoxy; however, for a high-power and high-brightness LED, which is driven by a much higher current and therefore generates heat several times higher than that of the conventional LED, epoxy is not an ideal encapsulation material, despite its advantageously high hardness. This is because epoxy is not resistant to high temperature, tends to be damaged by the short-wavelength radiation of white LEDs, and may easily deteriorate and discolor as a result.

In order to overcome the shortcomings of epoxy, other encapsulation materials were developed for use, such as silicone or hybrid compounds of epoxy and silicone. Silicone has higher heat resistance than epoxy, can disperse blue and near-ultraviolet light, and hence is less susceptible to deterioration and discoloration attributable to electric current and short-wavelength radiation when compared with epoxy.

Referring to FIG. 1 for a sectional view of a conventional LED 10, the LED 10 includes: an LED seat 11, which includes a supporting and heat-dissipating portion 111 and at least two electrode pins 112; an LED chip 12, which is provided on the supporting and heat-dissipating portion 111 and electrically connected to the corresponding electrode pins 112 by at least two wires 13; and an optical lens 14, which is configured to cover and protect the LED chip 12 and is made of an optical resin for encapsulation.

The optical lens 14 is formed into the desired shape by applying the optical resin to the LED 10 and then curing the optical resin. The optical lens 14 protects the LED chip 12 from being affected by the environment. For instance, the optical lens 14 can protect the LED chip 12 from being dampened and damaged by moisture in the environment as well as protect the wires 13 on the LED chip 12 from being broken by external force.

However, the optical lens 14 nowadays is typically a single-layer structure and does not have adequate hardness. When the LED 10 is being installed or operated, such as when the LED 10 is directly pressed so as to be installed on a circuit board, the external pressing force is transferred by the optical lens 14 with insufficient hardness to the interior of the LED 10 and applied to the LED chip 12. Consequently, the wires 13 on the LED chip 12 may be broken and thus form an open circuit in the LED 10, thereby rendering the LED 10 useless.

Hence, the manufacturing method and structure of the aforesaid conventional LED are obviously inadequate and defective in terms of process, product structure, and use, so further improvement is needed. However, while the LED industry has endeavored to find a solution to the foregoing problems, no suitable designs have been developed yet. Now that existing methods and products are flawed, and the development of new designs is unsuccessful, it is imperative for the LED industry to create a novel manufacturing method and structure of LEDs, wherein the LEDs are provided with multilayered optical lenses.

In view of the drawbacks of the manufacturing method and structure of the conventional LED, the inventor of the present invention made active efforts in related research and innovation by incorporating professional knowledge and academic theories into years of practical experience in product design, with the intention of providing a novel and practical manufacturing method and structure of an LED with a multilayered optical lens, as an improvement over the manufacturing method and structure of the conventional LED. After continuous research and repeated trials and modifications, the subject matter of the present invention is finally obtained and proven to have practical value.

### BRIEF SUMMARY OF THE INVENTION

It is an objective of the present invention to overcome the shortcomings of the manufacturing method and structure of the conventional LED by providing a novel manufacturing method and structure of an LED. The technical problem to be solved is to provide a manufacturing method and a structure of an LED with a multilayered optical lens, wherein the multilayered optical lens includes an inner protective layer whose hardness is higher than that of an outer protective layer. The inner protective layer with the higher hardness serves to shield the LED chip and wire connecting points thereof. Specifically, the inner protective layer can protect the LED chip from damage, and wires connected to the LED chip from breakage, so that the present invention is rendered more effective.

It is another objective of the present invention to provide a structure of a multilayered optical lens that is applicable to an LED structure so as to make the present invention more useful.

It is yet another objective of the present invention to provide a manufacturing method of a multilayered optical lens that is applicable to an LED encapsulation process so as to make the present invention even more useful.

The above objectives as well as the technical problems to be addressed by the present invention are achieved and solved by the following technical solution. A manufacturing method of an LED with a multilayered optical lens according to the present invention includes the steps of: providing an LED chip; forming at least one inner protective layer that covers and protects the LED chip and wire connecting points thereof; and forming an outer protective layer that covers the said inner protective layer; wherein both the said inner protective layer and the outer protective layer are optical resin layers, and the said inner protective layer has a higher hardness than the outer protective layer.

The above objectives as well as the technical problems to be addressed by the present invention are further achieved and solved by the following technical features.

In the aforesaid manufacturing method of an LED with a multilayered optical lens, the said inner protective layer has a refractive index higher than or equal to that of the outer protective layer.

In the aforesaid manufacturing method of an LED with a multilayered optical lens, the said inner protective layer is made of silicone, epoxy, or a hybrid compound thereof.

In the aforesaid manufacturing method of an LED with a multilayered optical lens, the outer protective layer is made of silicone, epoxy, or a hybrid compound thereof.

In the aforesaid manufacturing method of an LED with a multilayered optical lens, the said inner protective layer is further mixed with a wavelength conversion material, a brightness enhancing material, a diffusion material, or a combination thereof.

In the aforesaid manufacturing method of an LED with a multilayered optical lens, the outer protective layer is further mixed with a wavelength conversion material, a brightness enhancing material, a diffusion material, or a combination thereof.

The above objectives as well as the technical problems to be addressed by the present invention are also achieved and solved by the following technical solution. A structure of an LED with a multilayered optical lens according to the present invention includes: an LED chip; at least one inner protective layer that covers and protects the LED chip and wire connecting points thereof; and an outer protective layer that covers the said inner protective layer; wherein both the said inner protective layer and the outer protective layer are optical resin layers, and the said inner protective layer has a higher hardness than the outer protective layer.

The above objectives as well as the technical problems to be addressed by the present invention are further achieved and solved by the following technical features.

In the aforesaid structure of an LED with a multilayered optical lens, the said inner protective layer has a refractive index higher than or equal to that of the outer protective layer.

In the aforesaid structure of an LED with a multilayered optical lens, the said inner protective layer is made of silicone, epoxy, or a hybrid compound thereof.

In the aforesaid structure of an LED with a multilayered optical lens, the outer protective layer is made of silicone, epoxy, or a hybrid compound thereof.

In the aforesaid structure of an LED with a multilayered optical lens, the said inner protective layer is further mixed with a wavelength conversion material, a brightness enhancing material, a diffusion material, or a combination thereof.

In the aforesaid structure of an LED with a multilayered optical lens, the outer protective layer is further mixed with a wavelength conversion material, a brightness enhancing material, a diffusion material, or a combination thereof.

The above objectives as well as the technical problems to be addressed by the present invention are also achieved and solved by the following technical solution. A manufacturing method of a multilayered optical lens according to the present invention is applicable to an LED encapsulation process and includes the steps of: forming at least one inner protective layer that covers and protects an LED chip and wire connecting points thereof; and forming an outer protective layer that covers the said inner protective layer; wherein both the said inner protective layer and the outer protective layer are optical resin layers, and the said inner protective layer has a higher hardness than the outer protective layer.

The above objectives as well as the technical problems to be addressed by the present invention are further achieved and solved by the following technical features.

In the aforesaid manufacturing method of a multilayered optical lens, the said inner protective layer has a refractive index higher than or equal to that of the outer protective layer.

In the aforesaid manufacturing method of a multilayered optical lens, the said inner protective layer is made of silicone, epoxy, or a hybrid compound thereof.

In the aforesaid manufacturing method of a multilayered optical lens, the outer protective layer is made of silicone, epoxy, or a hybrid compound thereof.

In the aforesaid manufacturing method of a multilayered optical lens, the said inner protective layer is further mixed with a wavelength conversion material, a brightness enhancing material, a diffusion material, or a combination thereof.

In the aforesaid manufacturing method of a multilayered optical lens, the outer protective layer is further mixed with a wavelength conversion material, a brightness enhancing material, a diffusion material, or a combination thereof.

The above objectives as well as the technical problems to be addressed by the present invention are also achieved and solved by the following technical solution. A structure of a multilayered optical lens according to the present invention is applicable to an LED structure and includes: at least one inner protective layer that covers and protects an LED chip and wire connecting points thereof; and an outer protective layer that covers the said inner protective layer; wherein both the said inner protective layer and the outer protective layer are optical resin layers, and the said inner protective layer has a higher hardness than the outer protective layer.

The above objectives as well as the technical problems to be addressed by the present invention are further achieved and solved by the following technical features.

In the aforesaid structure of a multilayered optical lens, the said inner protective layer has a refractive index higher than or equal to that of the outer protective layer.

In the aforesaid structure of a multilayered optical lens, the said inner protective layer is made of silicone, epoxy, or a hybrid compound thereof.

In the aforesaid structure of a multilayered optical lens, the outer protective layer is made of silicone, epoxy, or a hybrid compound thereof.

In the aforesaid structure of a multilayered optical lens, the said inner protective layer is further mixed with a wavelength conversion material, a brightness enhancing material, or a combination thereof.

In the aforesaid structure of a multilayered optical lens, the outer protective layer is further mixed with a wavelength conversion material, a brightness enhancing material, or a combination thereof.

Compared with the prior art, the present invention is obviously more advantageous and more beneficial. Through the aforesaid technical solutions, the present invention at least provides the following advantages and benefits:

1. By forming the multilayered optical lens whose inner and outer protective layers have different hardnesses, the LED chip and its wire connecting points are prevented from damage by external force.

2. The inner protective layer with the higher hardness prevents wires of the LED from being broken by external force.

3. The multilayered optical lens with different hardnesses can absorb external force.

4. The multilayered optical lens with different hardnesses is enhanced in resistance to external force.

In summary, the present invention relates to a manufacturing method and a structure of an LED with a multilayered optical lens. The manufacturing method of an LED with a multilayered optical lens includes the steps of: providing an LED chip; forming an inner protective layer that covers and protects the LED chip and wire connecting points thereof; and forming an outer protective layer that covers the inner protective layer; wherein both the inner protective layer and the outer protective layer are optical resin layers, and the inner protective layer has a higher hardness than the outer protective layer. The inner protective layer with the higher hardness can resist external force transmitted by the outer protective layer and thereby protect the LED chip and the wire connecting points thereof. As a consequence, the LED chip and wires connected thereto are prevented from damage or breakage which may otherwise result from the external force. The present invention also provides a structure of a multilayered optical lens that is applicable to an LED structure, as well as a manufacturing method of a multilayered optical lens that is applicable to an LED encapsulation process, so that the present invention is more suitable for practical use. The multilayered optical lens includes an inner protective layer whose hardness is higher than that of an outer protective layer. Thus, the inner protective layer with the higher hardness serves to protect an LED chip and wire connecting points thereof. More particularly, the inner protective layer can prevent the LED chip from damage and wires connected to the LED chip from breakage, so that the present invention is highly suitable for practical use. The present invention has the foregoing advantages and practical value: provides significant improvement in manufacturing process, product structure, and function; involves substantial inventive steps technically; is convenient to use and practical; produces considerably better effects than the manufacturing method and structure of the conventional LED; and therefore is a truly novel, non-obvious, and useful design.

The foregoing description is only a summary of the technical solutions of the present invention. In order to better demonstrate the technical means adopted by the present invention and thereby enable implementation of the present invention according to the contents disclosed herein, and in order for the above and other objectives as well the characteristics and advantages of the present invention to be readily understood, several preferred embodiment of the present invention are presented below and described in detail in conjunction with the accompanying drawings.

### BRIEF DESCRIPTION OF THE SEVERAL VIEWS OF THE DRAWINGS

FIG. 1 is a sectional view of a conventional LED;

FIG. 2 is a flowchart of a manufacturing method of an LED with a multilayered optical lens according to the present invention;

FIG. 3A is a sectional view of a structure of an LED without the multilayered optical lens;

FIG. 3B is a sectional view of a structure of an LED formed with an inner protective layer according to the present invention;

FIG. 3C is a sectional view of a structure of an LED with the multilayered optical lens according to the present invention;

FIG. 4 is a sectional view of a structure of an LED according to the present invention whose inner protective layer is mixed with an additional material; and

FIG. 5 is a sectional view of a structure of an LED according to the present invention whose outer protective layer is mixed with an additional material.

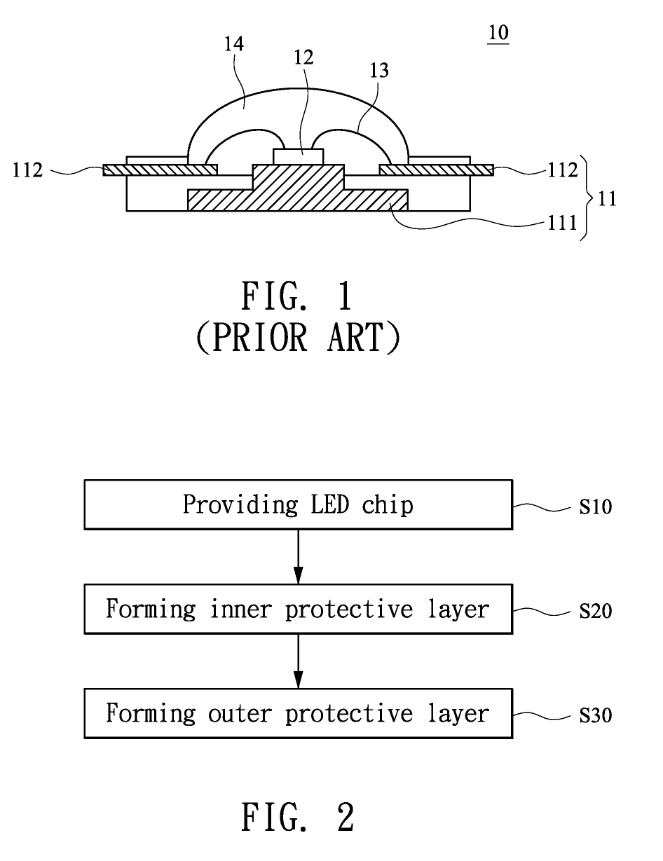

### DETAILED DESCRIPTION OF THE INVENTION

The technical means adopted by the present invention to achieve the intended objectives as well as the effects produced by the present invention are further elucidated by a detailed description of the preferred embodiments in conjunction with the accompanying drawings. More particularly, the manufacturing method and structure of an LED with a multilayered optical lens according to the present invention are detailed hereinafter with respect to their modes of implementation, process, steps, structure, characteristics, and effects.

The foregoing and other technical contents, features, and effects of the present invention are clearly demonstrated by the following detailed description of the preferred embodiments and the accompanying drawings. The modes of implementation are expounded to enable a thorough understanding of the technical means adopted by the present invention to achieve the intended objectives and of the effects produced by the present invention. However, it should be noted that the accompanying drawings are provided for illustrative purposes only and are not intended to limit the present invention in any way.

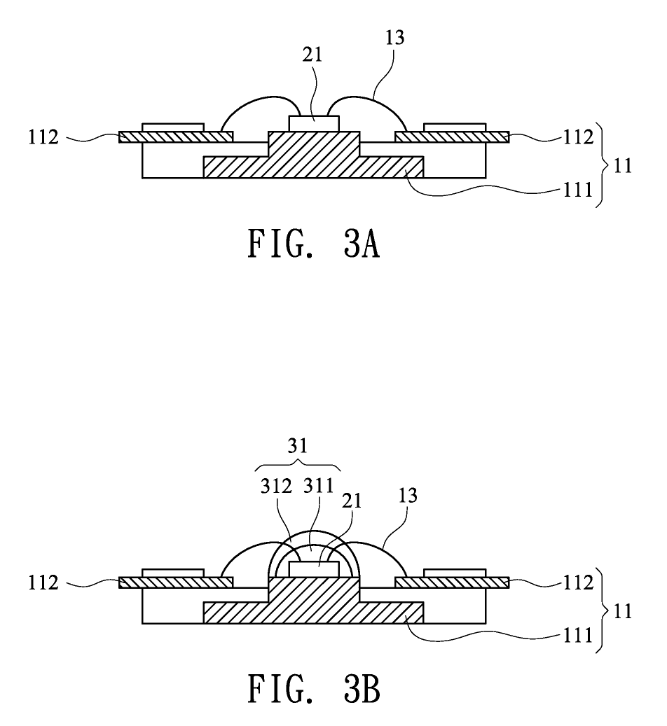

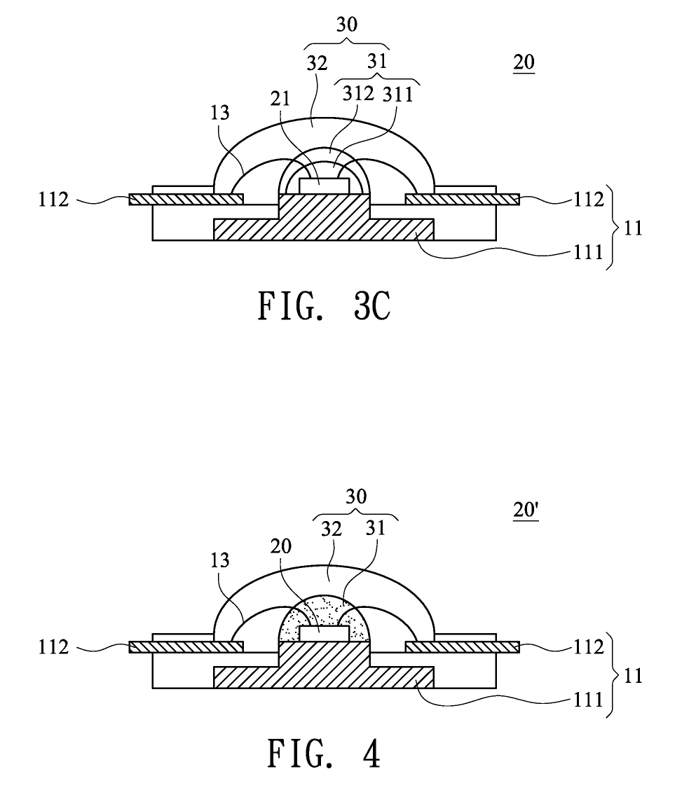

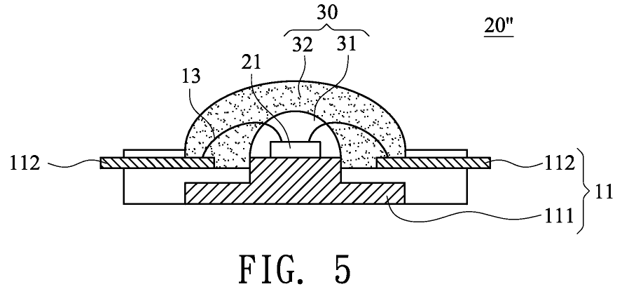

Please refer to FIG. 2 through FIG. 5, wherein FIG. 2 is a flowchart of a manufacturing method of an LED 20 with a multilayered optical lens 30 according to the present invention; FIG. 3A is a sectional view of a structure of an LED without the multilayered optical lens 30; FIG. 3B is a sectional view of a structure of an LED formed with an inner protective layer 31 according to the present invention; FIG. 3C is a sectional view of a structure of an LED 20 with the multilayered optical lens 30 according to the present invention; FIG. 4 is a sectional view of a structure of an LED 20′ according to the present invention whose inner protective layer 31 is mixed with an additional material; and FIG. 5 is a sectional view of a structure of an LED 20″ according to the present invention whose outer protective layer 32 is mixed with an additional material.

### FIRST EMBODIMENT

Please refer to FIG. 2 for a flowchart of a manufacturing method of an LED 20 with a multilayered optical lens 30 according to the present invention. According to a first embodiment of the present invention, a manufacturing method of an LED 20 with a multilayered optical lens 30 (as shown in FIG. 3C) includes the steps of: providing an LED chip (S10); forming at least one inner protective layer (S20); and forming an outer protective layer (S30). Therein, the inner protective layer 31 and the outer protective layer 32 are both optical resin layers, and the inner protective layer 31 has a higher hardness than the outer protective layer 32.

The step of providing an LED chip (S10) is described as follows. Referring to FIG. 3A for a sectional view of a structure of an LED without the multilayered optical lens 30, an LED chip 21 is provided, wherein the LED chip 21 is already fixed on an LED seat 11 and has completed electrical connection by means of a wire bonding technique. The LED chip 21 is, for example, a blue, red, green, or ultraviolet LED.

The step of forming an inner protective layer (S20) is carried out in the following manner. Referring to FIG. 3B, which is a sectional view of a structure of an LED formed with the inner protective layer 31 according to the present invention, the inner protective layer 31 is formed to cover and protect the LED chip 21 and its wire connecting points. The inner protective layer 31 is made of silicone, epoxy, or a hybrid compound of both. To increase its hardness, the inner protective layer 31 can also be made of any material that contributes to enhancing hardness. Furthermore, in order for the inner protective layer 31 to better protect the LED chip 21 and its wire connecting points, a plurality of the inner protective layers 31 can be formed, wherein the hardness of the plural inner protective layers 31 decreases from inside out such that the inner protective layers 31 closer to the LED chip 21 have a higher level of hardness. Thus, the LED chip 21 receives increased protection, and wires connected to the LED chip 21 are effectively prevented from breakage.

The step of forming an outer protective layer (S30) is detailed below. Referring to FIG. 3C, which is a sectional view of a structure of the LED 20 with the multilayered optical lens 30 according to the present invention, the outer protective layer 32 is formed to cover the inner protective layer 31. The outer protective layer 32 is also made of a material selected from silicone, epoxy, and a hybrid compound thereof. Nevertheless, the outer protective layer 32 must have a lower hardness than the inner protective layer 31. The inner protective layer 31 with the higher hardness serves to resist external force transmitted by the outer protective layer 32, thereby preventing the LED chip 21 and its wire connecting points from damage which may otherwise result from the external force.

To increase the light-emitting efficiency of the LED 20, a difference of refractive indices is created between the inner protective layer 31 and the outer protective layer 32. More specifically, the inner protective layer 31 has a higher refractive index than the outer protective layer 32 so that total internal reflection is prevented by the difference of refractive indices to enhance light emission. Besides, the refractive index of the inner protective layer 31 can also be equal to that of the outer protective layer 32. Moreover, the shapes of the inner protective layer 31 and the outer protective layer 32 may vary with the desired light emission pattern and be planar, convex, ball-shaped, and so on.

In order to provide the LED 20 with desirable features (such as increased light emission uniformity and brightness, different colors, etc.) and thus broaden its range of application, the inner protective layer 31 and/or the outer protective layer 32 can be mixed with a wavelength conversion material, a brightness enhancing material, a diffusion material, or a combination thereof.

For example, in order for the LED 20 to emit white light, a blue LED chip 21 is used while the inner protective layer 31 or the outer protective layer 32 is mixed with a wavelength conversion material that emits yellow light when excited by blue light, as shown in FIG. 4 and FIG. 5. Thus, the blue light is mixed with the yellow light to enable LEDs 20′ and 20″ to emit white light.

As another example, in order to increase brightness of the LED 20, the outer protective layer 32 or the inner protective layer 31 is mixed with a brightness enhancing material such as titanium dioxide (TiO₂), as shown in FIG. 4 and FIG. 5. Titanium dioxide enhances light reflection and therefore increases brightness of the LEDs 20′ and 20″. Alternatively, in order to increase light emission uniformity of the LED 20, the outer protective layer 32 or the inner protective layer 31 is mixed with a diffusion material that promotes light scattering, as shown in FIG. 4 and FIG. 5, thus rendering the light emitted by the LEDs 20′ and 20″ more uniform. It is also feasible to mix a wavelength conversion material into the inner protective layer 31, and a diffusion material into the outer protective layer 32, so as to enhance the properties of the LEDs 20′ and 20″.

### SECOND EMBODIMENT

As shown in FIG. 3C, a structure of an LED 20 with a multilayered optical lens 30 according to a second embodiment of the present invention includes an LED chip 21, at least one inner protective layer 31, and an outer protective layer 32, wherein both the inner protective layers 31 and the outer protective layer 32 are optical resin layers, and the inner protective layers 31 have a higher hardness than the outer protective layer 32.

The LED chip 21 is fixed on an LED seat 11, and at least two wires 13 are connected respectively between wire connecting points of the LED chip 21 and electrode pins 112 of the LED seat 11 by a wire bonding technique, thereby completing electrical connection of the LED 20. The LED chip 21 is, for example, a blue, red, green, or ultraviolet LED chip.

The inner protective layers 31 directly cover and thus protect the LED chip 21 and its wire connecting points. As shown in FIG. 3C, the present embodiment is provided with two inner protective layers 31, namely a first inner protective layer 311 and a second inner protective layer 312.

The first inner protective layer 311 is in direct contact with the LED chip 21 and its wire connecting points while the second inner protective layer 312 covers the first inner protective layer 311. The second inner protective layer 312 has a lower hardness than the first inner protective layer 311. In addition, the second inner protective layer 312 has a refractive index lower than or equal to that of the first inner protective layer 311 so as to enhance light emission by the LED 20.

The outer protective layer 32 covers the inner protective layers 31 and has a lower hardness than the inner protective layers 31. When an external force is applied to the multilayered optical lens 30 of the LED 20, the outer protective layer 32, due to its lower hardness, transmits the external force to the interior of the multilayered optical lens 30. On the other hand, the inner protective layer 31, owing to its higher hardness, resists the external force and therefore prevents the external force from being transmitted to the LED chip 21 and its wire connecting points. Hence, the LED chip 21 is effectively protected from damage by compression of the external force, and the wires 13 are prevented from breaking at the wire connecting points. For instance, the hardness of the inner protective layers 31 can be Shore D40 while the hardness of the outer protective layer 32 is Shore D30.

In order to increase light-emitting efficiency of the LED 20, a difference of refractive indices is created between the inner protective layers 31 and the outer protective layer 32. More specifically, the inner protective layers 31 have a higher refractive index than the outer protective layer 32 so that total internal reflection is prevented by the difference of refractive indices, thus enhancing light emission. Besides, the refractive index of the inner protective layers 31 can also be equal to that of the outer protective layer 32. Moreover, the shapes of the inner protective layers 31 and the outer protective layer 32 may vary with the desired light emission pattern and be planar, convex, ball-shaped, and so on.

Please refer to FIG. 4 and FIG. 5, wherein FIG. 4 is a sectional view of a structure of an LED 20′ according to the present invention whose inner protective layer 31 is mixed with an additional material; and FIG. 5 is a sectional view of a structure of an LED 20″ according to the present invention whose outer protective layer 32 is mixed with an additional material. In order to provide the LED 20 with desirable features (such as increased light emission uniformity and brightness, different colors, etc.) and thus broaden its range of application, the inner protective layer 31 and/or the outer protective layer 32 can be mixed with a wavelength conversion material, a brightness enhancing material, a diffusion material, or a combination thereof.

For example, in order for the LED 20 to emit white light, a blue LED chip 21 is used while the inner protective layer 31 or the outer protective layer 32 is mixed with a wavelength conversion material that emits yellow light when excited by blue light. Thus, the blue light is mixed with the yellow light to enable the LEDs 20′ and 20″ to emit white light.

As another example, in order to increase brightness of the LED 20, the outer protective layer 32 or the inner protective layer 31 is mixed with a brightness enhancing material, such as titanium dioxide. Titanium dioxide enhances light reflection and therefore increases brightness of the LEDs 20′ and 20″. Alternatively, in order to increase light emission uniformity of the LED 20, the outer protective layer 32 or the inner protective layer 31 is mixed with a diffusion material that promotes light scattering, thus rendering the light emitted by the LEDs 20′ and 20″ more uniform. It is also feasible to mix a wavelength conversion material into the inner protective layer 31, and a diffusion material into the outer protective layer 32, so as to enhance the properties of the LEDs 20′ and 20″.

As can be known from the foregoing description of the embodiments, the inner protective layer 31 with the higher hardness not only provides direct protection to the LED chip 21 and its wire connecting points, but also resists external force transmitted by the outer protective layer 32 with the lower hardness, thus effectively preventing the LED chip 21 from being damaged by the external force, and the wires 13 from breaking at the wire connecting points.

The embodiments disclosed herein are only the preferred embodiments of the present invention and are not intended to limit the present invention in any way. A person skilled in the art may readily make minor changes or modifications to the disclosed embodiments and produce equivalent embodiments according to the technical contents set forth herein. All such minor or equivalent changes or modifications which do not depart from the concept and substance of the present invention should be encompassed by the appended claims.

### INDUSTRIAL APPLICABILITY

According to the present invention, the inner protective layer with the higher hardness is configured to directly protect the LED chip and its wire connecting points and resist external force transmitted by the outer protective layer with the lower hardness, thereby protecting the LED chip and its wire connecting points. Consequently, the LED chip is effectively prevented from being damaged by the external force, and the wires from breaking at the wire connecting points. Therefore, the present invention is highly practical and useful.

What is claimed is:

1. A manufacturing method of a light-emitting diode (LED) with a multilayered optical lens, comprising steps of:
providing an LED chip;
forming at least one inner protective layer that covers and protects the LED chip and wire connecting points thereof; and
forming an outer protective layer that covers the said inner protective layer;
wherein both the said inner protective layer and the outer protective layer are optical resin layers, and the said inner protective layer has a higher hardness than the outer protective layer.

2. The manufacturing method of claim 1, wherein the said inner protective layer has a refractive index higher than or equal to a refractive index of the outer protective layer.

3. The manufacturing method of claim 1, wherein the said inner protective layer is made of silicone, epoxy, or a hybrid compound thereof.

4. The manufacturing method of claim 1, wherein the outer protective layer is made of silicone, epoxy, or a hybrid compound thereof.

5. The manufacturing method of claim 1, wherein the said inner protective layer is further mixed with a wavelength conversion material, a brightness enhancing material, a diffusion material, or a combination thereof.

6. The manufacturing method of claim 1, wherein the outer protective layer is further mixed with a wavelength conversion material, a brightness enhancing material, a diffusion material, or a combination thereof.

7. A structure of a light-emitting diode (LED) with a multilayered optical lens, comprising:
an LED chip;
at least one inner protective layer that covers and protects the LED chip and wire connecting points thereof; and
an outer protective layer that covers the said inner protective layer;
wherein both the said inner protective layer and the outer protective layer are optical resin layers, and the said inner protective layer has a higher hardness than the outer protective layer.

8. The structure of claim 7, wherein the said inner protective layer has a refractive index higher than or equal to a refractive index of the outer protective layer.

9. The structure of claim 7, wherein the said inner protective layer is made of silicone, epoxy, or a hybrid compound thereof.

10. The structure of claim 7, wherein the outer protective layer is made of silicone, epoxy, or a hybrid compound thereof.

11. The structure of claim 7, wherein the said inner protective layer is further mixed with a wavelength conversion material, a brightness enhancing material, a diffusion material, or a combination thereof.

12. The structure of claim 7, wherein the outer protective layer is further mixed with a wavelength conversion material, a brightness enhancing material, a diffusion material, or a combination thereof.

13. A structure of a multilayered optical lens, the structure being applicable to a light-emitting diode (LED) structure and comprising:
at least one inner protective layer that covers and protects an LED chip and wire connecting points thereof; and
an outer protective layer that covers the said inner protective layer;
wherein both the said inner protective layer and the outer protective layer are optical resin layers, and the said inner protective layer has a higher hardness than the outer protective layer.

14. The structure of claim 13, wherein the said inner protective layer has a refractive index higher than or equal to a refractive index of the outer protective layer.

15. The structure of claim 13, wherein the said inner protective layer is made of silicone, epoxy, or a hybrid compound thereof.

16. The structure of claim 13, wherein the outer protective layer is made of silicone, epoxy, or a hybrid compound thereof.

17. The structure of claim 13, wherein the said inner protective layer is further mixed with a wavelength conversion material, a brightness enhancing material, or a combination thereof.

18. The structure of claim 13, wherein the outer protective layer is further mixed with a wavelength conversion material, a brightness enhancing material, or a combination thereof.
